(19) United States
(12) Patent Application Publication
(10) Pub. No.: US 2026/0100337 A1
(43) Pub. Date: Apr. 9, 2026

(54) PLASMA ETCHING METHOD

(71) Applicant: AJOUUNIVERSITY INDUSTRY-ACADEMIC COOPERATION FOUNDATION, Suwon-si, Gyeoggi-do (KR)

(72) Inventors: Chang-Koo KIM, Seoul (KR); Sang Hyun YOU, Suwon-si (KR)

(73) Assignee: AJOUUNIVERSITY INDUSTRY-ACADEMIC COOPERATION FOUNDATION, Suwon-si, Gyeoggi-do (KR)

(21) Appl. No.: 19/115,375

(22) PCT Filed: Oct. 4, 2023
(86) PCT No.: PCT/KR2023/015167

§ 371 Date: Mar. 26, 2025

(30) Foreign Application Priority Data
Dec. 15, 2022 (KR) 10-2022-0176251

(51) Int. Cl. H01J 37/32; C09K 13/00; H10P 50/28

(52) U.S. Cl. CPC H01J 37/32449; C09K 13/00; H10P 50/283; H01J 2237/334

(57) ABSTRACT

Disclosed is a plasma etching method. The method may include a first step of vaporizing liquid heptafluoroisopropyl methyl ether (HFE-347mmy) and liquid pentafluoropropanol (PFP); a second step of supplying a discharge gas containing the vaporized HFE-347mmy, the vaporized PFP, and argon gas to a plasma chamber in which an etching target is disposed; and a third step of discharging the discharge gas to generate plasma and of plasma-etching the etching target using the generated plasma.

### FIELD

The present disclosure relates to a plasma etching method, and more particularly, to a plasma etching method using a gas obtained by mixing HFE-347mmy and PFP having a low GWP (global warming potential) as a discharge gas.

### DESCRIPTION OF RELATED ART

In the manufacture of semiconductor devices, an etching structure having a high aspect ratio is required due to high density of integrated circuits and miniaturization of devices. The high aspect ratio structure is mainly manufactured through plasma etching, and etching for obtaining the high aspect ratio structure mainly uses Perfluoro compound (PFC) plasma.

The PFC gas is chemically stable, such that the average residence time thereof in the atmosphere is long, and the GWP thereof is very high, that is, higher than 6,500 times of that of CO₂. Thus, under a small amount of emissions thereof, the global warming effect is great. The PFC gas is one of the six major greenhouse gases (CO₂, CH₄, N₂O, HFC, PFC, and SF₆) and is used in various industrial sectors, and in particular, a large amount thereof is used and emitted in semiconductor device manufacturing processes.

Members of the World Semiconductor Council (WSC) have voluntarily signed an agreement to reduce PFC gas emissions by 10% from 1999 to 2010, and have agreed to a program to reduce gas emissions by 32% compared to 2010 from 2011 to 2020. However, as the degree of integration of semiconductor devices increases, the proportion of the etching process has increased due to the miniaturization of the structure, and the annual emission of PFC gas continues to increase. Efforts are being made to reduce emissions through various methods such as decomposition, separation, and collection of the emitted PFC gas to reduce emissions of the PFC gas. However, the use of the GWP gas with high PFC has a fundamental limitation.

Representative PFC gases used in etching silicon oxide (SiO₂) or silicon nitride (Si₃N₄) in a current semiconductor device manufacturing process may include CF₄, C₂F₆, c-C₄F₈, and the like. During plasma etching using the PFC gas, a fluorocarbon thin film caused by CFx radicals is formed on the surface of SiO₂ or Si₃N₄, and the fluorocarbon thin film serves as a source of etchants during etching, hinders the diffusion of ions and radicals, and protects the wall surface of the etch profile to determine the shape. However, excessive formation of the fluorocarbon thin film in an etching process of a hole pattern structure such as a via or a contact has a problem in that an etch stop occurs.

Therefore, there is a need for a new etchant that may replace the conventional PFC gas, is environmentally friendly due to low GWP, and has excellent etching ability to form a high aspect ratio etched structure, and a plasma etching method using the same.

### DISCLOSURE

### Technical Purpose

One purpose of the present disclosure is to provide a plasma etching method using a mixed gas of HFE-347mmy and PFP having a low global warming potential and excellent etching ability as a discharge gas.

### Technical Solution

A plasma etching method according to an embodiment of the present disclosure may include a first step of vaporizing liquid heptafluoroisopropyl methyl ether (HFE-347mmy) and liquid pentafluoropropanol (PFP): a second step of supplying a discharge gas containing the vaporized HFE-347mmy, the vaporized PFP, and argon gas to a plasma chamber in which an etching target is disposed; and a third step of discharging the discharge gas to generate plasma and of plasma-etching the etching target using the generated plasma.

In one embodiment, in order to vaporize the liquid HFE-347mmy and the liquid PFP and then supply the vaporized HFE-347mmy and the vaporized PFP to the plasma chamber, a first container receiving the liquid HFE-347mmy therein is heated to a first temperature higher than or equal to a boiling point of the HFE-347mmy, and a first connection pipe connecting the first container and the plasma chamber to each other is heated to a second temperature higher than the first temperature, and a second container receiving the liquid PFP therein is heated to a third temperature higher than or equal to a boiling point of the PFP, and a second connection pipe connecting the second container and the plasma chamber to each other is heated to a fourth temperature higher than the third temperature.

In one embodiment, a ratio of a flow rate of HFE-347mmy to a sum of flow rates of HFE-347mmy and PFP in the discharge gas is in a range of 10% to 90%.

In one embodiment, a ratio of the sum of the flow rates of the HFE-347mmy and the PFP and a flow rate of the argon gas is in a range of 1:1 to 1:3.

In one embodiment, a bias voltage applied to a substrate supporting the etching target thereon in the plasma chamber is in a range of −800 V to −400 V.

In one embodiment, the etching target is a silicon nitride film or a silicon oxide film.

### Effects of Disclosure

According to the present disclosure, the mixture of HFE-347mmy and PFP may replace the PFC gas having a high global warming effect, such that the semiconductor manufacturing processes using the mixture may be more environmentally friendly than the semiconductor manufacturing processes using the conventional PFC gas may be.

In addition, according to the present disclosure, when the mixed gas of HFE-347mmy and PFP is used as a discharge gas, a thinner and softer fluorocarbon thin film is formed, thereby increasing the etching rate on a silicon nitride film or a silicon oxide film.

### BRIEF DESCRIPTION OF DRAWINGS

FIG. 1 is a schematic diagram of a plasma etching apparatus capable of performing a plasma etching method according to an embodiment of the present disclosure.

FIG. 2 is a graph showing a change in an etching rate of silicon oxide (SiO₂) based on a change in a flow rate ratio of HFE-347mmy/PFP/Ar under various bias voltages in the plasma etching performed under the conditions as described in Table 2.

FIG. 3 is a graph showing a change in an etching rate of silicon nitride (Si₃N₄) based on a change in the flow rate ratio of HFE-347mmy/PFP/Ar under various bias voltages in a plasma etching performed under the conditions as described in Table 3.

FIG. 4 is a graph showing a change in a thickness of a steady-state fluorocarbon film formed on a surface of silicon oxide (SiO₂) based on a change in the flow rate ratio of HFE-347mmy/PFP/Ar in a plasma etching performed under the conditions as shown in Table 4.

FIG. 5 is a graph showing a change in the F/C ratio of a steady-state fluorocarbon film formed on the surface of silicon oxide (SiO₂) based on a change in the flow rate ratio of HFE-347mmy/PFP/Ar in a plasma etching performed under the conditions as shown in Table 4.

### DETAILED DESCRIPTIONS

Hereinafter, embodiments of the present disclosure will be described in detail with reference to the accompanying drawings. The present disclosure may be subjected to various changes and may have various forms. Thus, particular embodiments will be illustrated in the drawings and will be described in detail herein. However, this is not intended to limit the present disclosure to a specific disclosed form. It should be understood that the present disclosure includes all modifications, equivalents, and replacements included in the spirit and technical scope of the present disclosure. While describing the drawings, similar reference numerals are used for similar components.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

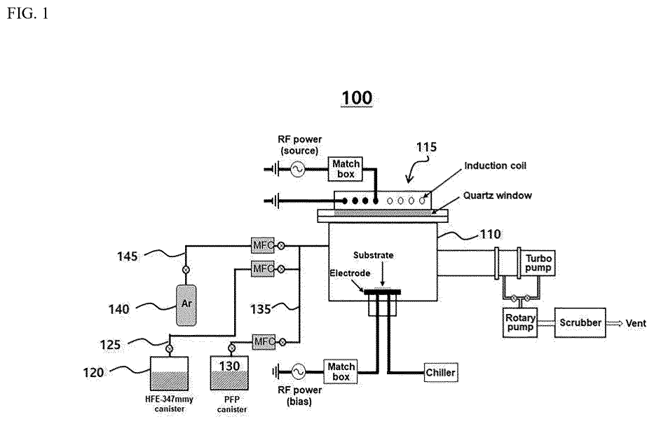

FIG. 1 is a schematic diagram of a plasma etching apparatus capable of performing a plasma etching method according to an embodiment of the present disclosure.

Referring to FIG. 1, a plasma etching method according to an embodiment of the present disclosure may include plasma-etching an etching target using a discharge gas including heptafluoroisopropyl methyl ether (HFE-347mmy), pentafluoropropanol (PFP), and argon gas in a plasma chamber in which the etching target is disposed.

The etching target is not particularly limited, but may generally be silicon oxide, silicon nitride, or the like, which functions as an insulating layer in a semiconductor device manufacturing process. For example, the etching target may be made of silicon oxide such as silicon dioxide or silicon nitride (Si₃N₄).

Each of the HFE-347mmy and PFP is known to have the physical properties shown in Table 1 as set forth below. HFE-347mmy and PFP have boiling points of 29° C. and 80° C., respectively, and thus exist in a liquid state at room temperature, and have GWPs of 353 and 42, respectively, which are significantly lower than GWPs of the conventional PFC compounds.

TABLE 1

| | Chemical Structure) | |
|---|---|---|
| | FIG. 6 | FIG. 7 |
| Chemical | (Heptafluoroisopropyl | Pentafluoropropanol(PFP) |
| name | methyl ether)(HFE-347mmy) | |
| Molecular | C₄H₃F₇O | C₃H₃F₅O |
| formula | | |
| Molecular | 200 | 150 |
| weight | | |
| (M.W.) | | |
| (g/mol) | | |
| Boiling | 29 | 80 |
| Point | | |
| (° C.) | | |
| GWP | 353 | 42 |

Referring back to FIG. 1, the plasma etching method according to the embodiment of the present disclosure may be performed using the plasma etching apparatus shown in FIG. 1. In one embodiment, a plasma etching apparatus 100 may include a plasma chamber 110, a first container 120, a second container 130, and a third container 140. The plasma chamber 110 may be coupled to a plasma source 115 and may include a discharge space receiving the etching target (‘wafer’) therein. The discharge space may receive the discharge gas from the first to third containers 120, 130, and 140, and the plasma source 115 may apply a discharge voltage to the discharge gas to generate plasma.

The first to third containers 120, 130, and 140 may be connected to the plasma chamber 110 via first to third connection pipes 125, 135, and 145, respectively. HFE-347mmy in a liquid state may be received in the first container 120, PFP in a liquid state may be received in the second container 130, and argon gas may be received in the third container 145.

The heptafluoroisopropyl methyl ether (HFE-347mmy) may be received in the first container 120. HFE-347mmy has a boiling point of about 29° C. and thus exists in a liquid phase at room temperature. Thus, in order to uniformly introduce the liquid HFE-347mmy into the plasma chamber 110, the HFE-347mmy may be vaporized and then may be provided into the discharge space of the plasma chamber 110. In one embodiment, the vaporization of the HFE-347mmy may be performed by heating the first container 120 receiving therein the liquid HFE-347mmy, and the connection pipe 125 connecting the first container 120 to the plasma chamber 110 to a temperature higher than the boiling point of the HFE-347mmy. For example, in order to prevent splashing of droplets, the first container 120 may be heated to a temperature of about 50 to 80° C., and the first connection pipe 125 may be heated to a temperature of about 85 to 140° C.

The pentafluoropropanol (PFP) may be received in the second container 130. The PFP has a boiling point of about 80° C. and thus exists in a liquid state at room temperature. Thus, in order to uniformly introduce the liquid PFP into the plasma chamber 110, the PFP may be vaporized and then provided to the discharge space of the plasma chamber 110. In one embodiment, the vaporization of the PFP may be performed by heating the second container 130 receiving the liquid PFP therein, and the second connection pipe 135 connecting the second container 130 and the plasma chamber 110 to a temperature above the boiling point of the PFP. For example, in order to prevent splashing of droplets, the second container 130 may be heated to a temperature of about 95 to 120° C., and the second connection pipe 135 may be heated to a temperature of about 125 to 140° C.

The heating of the first and second containers 120 and 130 and the first and second connection pipes 125 and 135 may be performed by an additional external device, for example, using a heating jacket. However, the heating device is not necessarily limited thereto, and any device capable of heating the container and the connecting pipe may be used as the heating device.

In one example, a mass flow controller may be additionally installed at an outlet of each of the first and second connection pipes 125 and 135. The mass flow controller may allow each of the vaporized HFE-347mmy and PFP to be fed to the discharge space of the plasma chamber 110 at a constant flow rate.

The argon gas received in the third container 140 may be supplied to the discharge space of the plasma chamber 110 through the third connection pipe 145 different from the first and second connection pipes 125 and 135.

The argon gas as a dilution gas together with the vaporized HFE-347mmy and PFP may be supplied into the plasma chamber. The argon gas may increase the plasma density and may perform anisotropic etching on the etching target via ion bombardment.

In one embodiment, a ratio of a flow rate of HFE-347mmy to a sum of flow rates of HFE-347mmy and PFP in the discharge gas may be in a range of about 10% to 90%. When the ratio of the flow rates of the HFE-347mmy and the PFP is within the above range, the etch rate of silicon oxide (SiO₂) or silicon nitride (Si₃N₄) may be improved. In addition, when the ratio of the flow rates of the HFE-347mmy and the PFP is within the above range, a thickness of the steady-state fluorocarbon film generated in the discharge plasma is reduced to promote the penetration of ions and radicals, such that the etching of the SiO₂ or the Si₃N₄ may be performed in a larger amount. Further, a F/C ratio of the fluorocarbon film is increased to form a thinner and softer fluorocarbon film, such that the etching rate of the SiO₂ or the Si₃N₄ may be increased.

For example, when the etching target is silicon oxide (SiO₂), a ratio of a flow rate of HFE-347mmy to a sum of flow rates of HFE-347mmy and PFP in the discharge gas may be in a range of about 10% to 90%, about 60% to 90%, or about 60% to 75%.

For example, when the etching target or an object to be etched is silicon nitride (Si₃N₄), a ratio of a flow rate of HFE-347mmy to a sum of flow rates of HFE-347mmy and PFP in the discharge gas may be in a range of about 10% to 90% or about 25% to 75%.

In one embodiment, in the discharge gas, a ratio between the sum of the flow rates of the HFE-347mmy and the PFP and a flow rate of the argon gas may be in a range of about 1:1 to 1:3. When the ratio between the sum of the flow rates of the HFE-347mmy and the PFP and the flow rate of the argon gas is within the above range, not only the etch rate of the SiO₂ or the Si₃N₄ of may be improved, but also the anisotropic etching characteristics may be improved.

In one embodiment, in the plasma etching method according to an embodiment of the present disclosure, a bias voltage applied to a substrate supporting the etching target thereon in the plasma chamber may be about −800V or lower, or about −1000V or lower. For example, the bias voltage may be in a range of about −800V to −400V. When the bias voltage exceeds −400V, an etch rate on the etching target may be excessively low. When the bias voltage is lower than −800V, a problem of only increasing power consumption may occur while additional improvement of the etch rate does not occur.

According to the plasma etching method of the present disclosure, while the mixed gas of HFE-347mmy, PFP and argon (Ar) having a significantly lower GWP (Global Warming Potential) than that of the conventional PFC gas is applied as the discharge gas, the plasma etching process is performed. Thus, compared to the plasma etching process using the conventional PFC gas, emission of greenhouse gases may be significantly reduced, and the plasma etching may be performed with excellent etching ability of the etching target such as a silicon nitride film or a silicon oxide film.

Hereinafter, more specific Examples and experimental Examples will be described. However, the following Examples are merely some embodiments of the present disclosure, and the scope of the present disclosure is not limited to the following Examples.

### EXAMPLES

Plasma etching was performed on several thin films under various conditions using a mixed gas of HFE-347mmy, PFP, and argon as the discharge gas. At this time, the discharge gas was supplied to the etching chamber at a flow rate of 30 sccm. In vaporizing HFE-347mmy and PFP and supplying the vaporized HFE-347mmy and PFP to the plasma chamber, the first container receiving the liquid HFE-347mmy therein was heated to 75° C., the first connection pipe connecting the first container and the plasma chamber to each other was heated to 90° C., the second container receiving the liquid PFP therein was heated to 110° C., and the second connection pipe connecting the second container and the plasma chamber to each other was heated to 130° C.

### Experimental Example 1

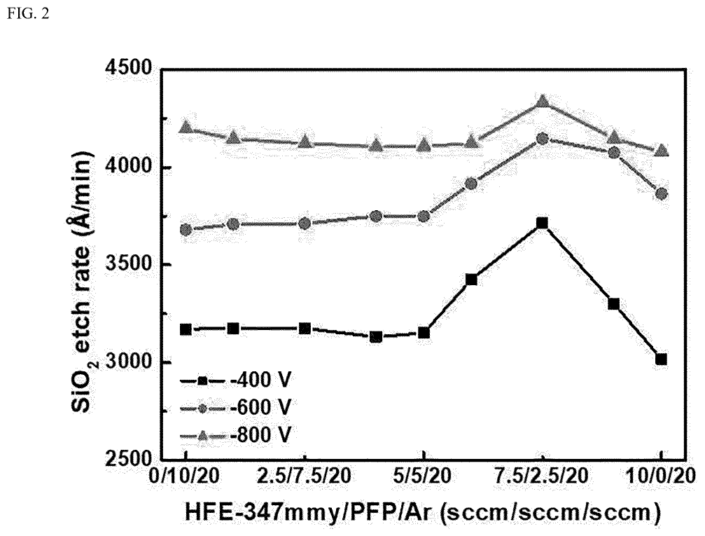

FIG. 2 is a graph showing a change in the etching rate of silicon oxide (SiO₂) based on a change in the flow rate ratio of HFE-347mmy/PFP/Ar under various bias voltages in a plasma etching performed under the conditions described in Table 2 as set forth below.

TABLE 2

| | |
|---|---|
| Source power (W) | 250 |
| Bias voltage (V) | −400, −600, −800 |
| Discharge gas | HFE-347mmy/PFP/Ar |
| Flow rate (sccm) | HFE-347mmy/PFP/Ar0/10/20, 1/9/20, |
| | 2.5/7.5/20, 4/6/20, 5/5/20, 6/4/20, 7.5/2.5/20, |
| | 9/1/20, 10/0/20 |
| Pressure (mTorr) | 10 |
| Electrode temperature | 15 |
| (° C.) | |

Referring to FIG. 2, the etching rate of silicon oxide was almost constant in a HFE-347mmy/PFP flow rate ratio of 0:10 to 5:5 in all bias voltages. Thereafter, as the HFE-347mmy/PFP flow rate ratio increases from 5:5 to 7.5:2.5 as the HFE-347mmy flow rate increases, the etching rate of silicon oxide increases. When the HFE-347mmy/PFP flow rate ratio becomes 7.5:2.5, the etching rate may be the greatest. As the HFE-347mmy/PFP flow rate ratio increases from 7.5:2.5 to 10:0, the etching rate decreases again

As the bias voltage increases so that the ion energy increases and thus the etching rate increases, the etching rate of the silicon oxide (SiO₂) increases.

### Experimental Example 2

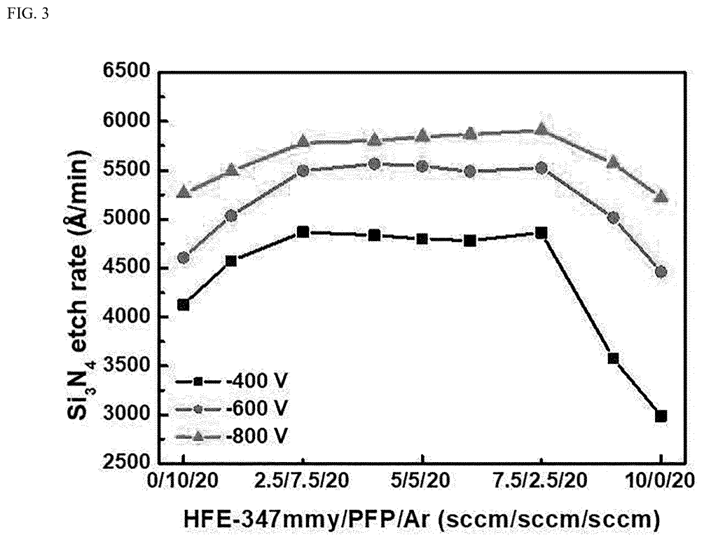

FIG. 3 is a graph showing a change in an etching rate of silicon nitride (Si₃N₄) based on a change in a flow rate ratio of HFE-347mmy/PFP/Ar under various bias voltages in a plasma etching performed under the conditions shown in Table 3 as set forth below.

TABLE 3

| | |
|---|---|
| Source power (W) | 250 |
| Bias voltage (V) | −400, −600, −800 |
| Discharge gas | HFE-347mmy/PFP/Ar |
| Flow rate (sccm) | HFE-347mmy/PFP/Ar0/10/20, 1/9/20, |
| | 2.5/7.5/20, 4/6/20, 5/5/20, 6/4/20, 7.5/2.5/20, |
| | 9/1/20, 10/0/20 |
| Pressure (mTorr) | 10 |
| Electrode temperature | 15 |
| (° C.) | |

Referring to FIG. 3, it may be identified that the etching rate of silicon nitride increases as the HFE-347mmy flow rate increases such that the HFE-347mmy/PFP flow rate ratio increases from 0:10 to 2.5:7.5 in all bias voltages. When the HFE-347mmy/PFP flow rate ratio was in the range of 2.5:7.5 to 7.5:2.5, the etching rate of silicon nitride was almost constant. Thereafter, as the HFE-347mmy flow rate increased such that the HFE-347mmy/PFP flow rate ratio increased from 7.5:2.5 to 10:0, the etching rate decreased again.

As the bias voltage increases, and thus the ion energy increases, the etching rate of the silicon nitride (Si₃N₄) increases.

### Experimental Example 3

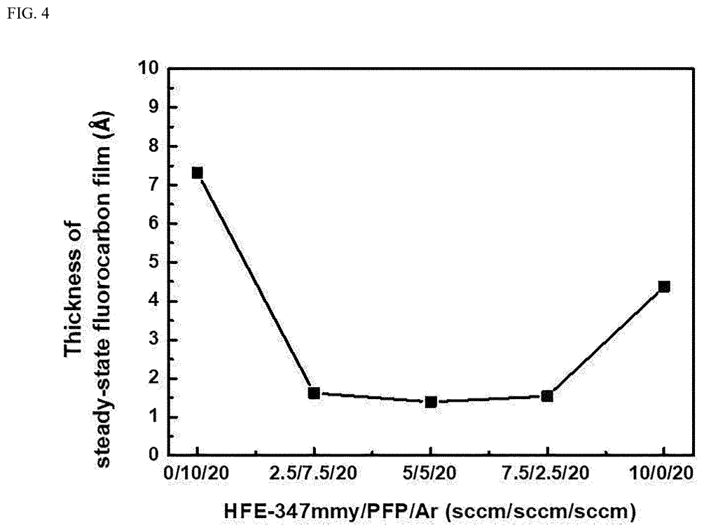

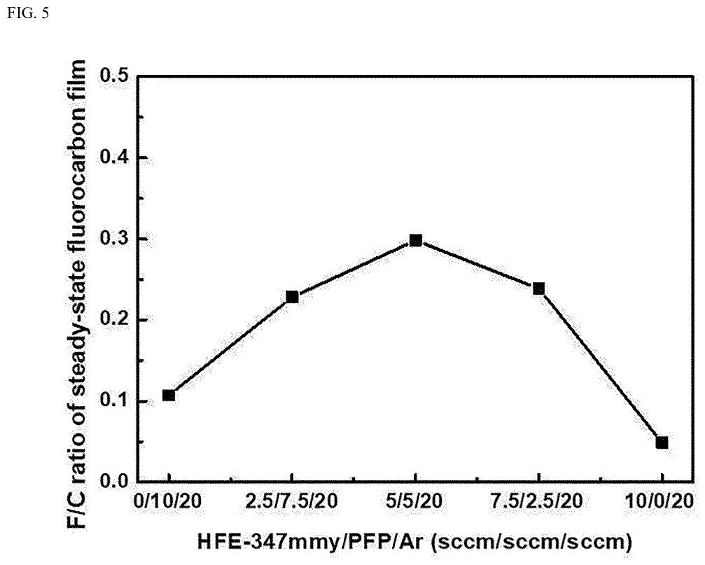

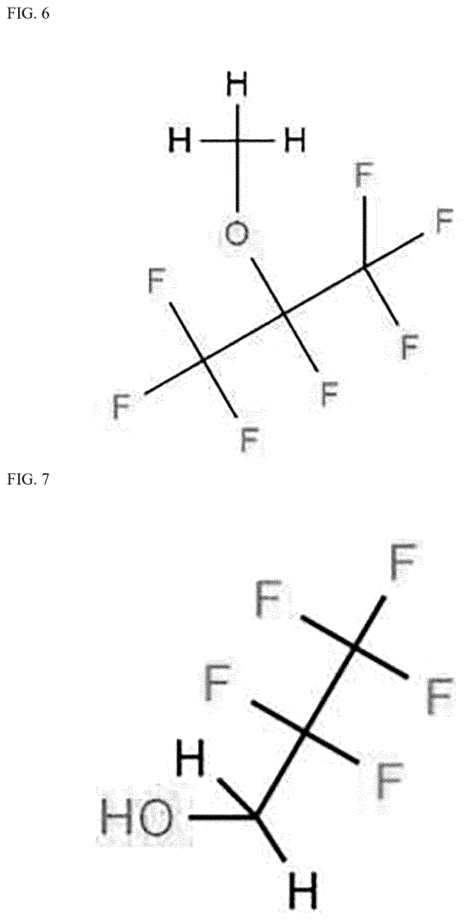

FIG. 4 is a graph showing a change in a thickness of a steady-state fluorocarbon film formed on a surface of silicon oxide (SiO₂) based on a change in the flow rate ratio of HFE-347mmy/PFP/Ar in a plasma etching performed under the conditions as shown in Table 4. FIG. 5 is a graph showing a change in the F/C ratio of a steady-state fluorocarbon film formed on the surface of silicon oxide (SiO₂) based on a change in the flow rate ratio of HFE-347mmy/PFP/Ar in a plasma etching performed under the conditions as shown in Table 4.

TABLE 4

| | |
|---|---|
| Source power (W) | 250 |
| Bias voltage (V) | −400 |
| Discharge gas | HFE-347mmy/PFP/Ar |
| Flow rate (sccm) | HFE-347mmy/PFP/Ar0/10/20, 2.5/7.5/20, |
| | 5/5/20, 7.5/2.5/20, 10/0/20 |
| Pressure (mTorr) | 10 |
| Electrode temperature | 15 |
| (° C.) | |

Referring to FIG. 4, it was identified that the thickness of the fluorocarbon thin film formed on the surface of the silicon oxide (SiO₂) was significantly reduced when a mixture of HFE-347mmy and PFP was used, compared to when HFE-347mmy or PFP was used alone. The thinner the thickness of the fluorocarbon thin film, the easier the penetration of ions and radicals thereto, so that the silicon oxide (SiO₂) substrate may be etched in a large amount. Further, referring to FIG. 5, it was identified that the F/C ratio of the fluorocarbon thin film increased when the mixture of HFE-347mmy and PFP was used, compared to when HFE-347mmy or PFP was used alone. When the F/C ratio increases, the fluorocarbon thin film is softer, and thus the silicon oxide (SiO₂) substrate may be etched in a large amount.

According to the above results, a thinner and softer fluorocarbon thin film is formed when the mixture of HFE-347mmy and PFP is used, compared to when HFE-347mmy or PFP is used alone. Thus, in an area in which HFE-347mmy and PFP are mixed with each other, an etching rate of silicon oxide (SiO₂) and silicon nitride (Si₃N₄) may increase compared to when HFE-347mmy or PFP is used alone.

Although the present disclosure has been described with reference to preferred embodiments of the present disclosure, those skilled in the art will understand that various modifications and changes may be made to the present disclosure without departing from the spirit and scope of the present disclosure as described in the claims below.

1. A plasma etching method comprising:
a first step of vaporizing liquid heptafluoroisopropyl methyl ether (HFE-347mmy) and liquid pentafluoropropanol (PFP);
a second step of supplying a discharge gas containing the vaporized HFE-347mmy, the vaporized PFP, and argon gas to a plasma chamber in which an etching target is disposed; and
a third step of discharging the discharge gas to generate plasma and of plasma-etching the etching target using the generated plasma.

2. The plasma etching method of claim 1, wherein in order to vaporize the liquid HFE-347mmy and the liquid PFP and then supply the vaporized HFE-347mmy and the vaporized PFP to the plasma chamber,
a first container receiving the liquid HFE-347mmy therein is heated to a first temperature higher than or equal to a boiling point of the HFE-347mmy, and a first connection pipe connecting the first container and the plasma chamber to each other is heated to a second temperature higher than the first temperature, and
a second container receiving the liquid PFP therein is heated to a third temperature higher than or equal to a boiling point of the PFP, and a second connection pipe connecting the second container and the plasma chamber to each other is heated to a fourth temperature higher than the third temperature.

3. The plasma etching method of claim 1, wherein a ratio of a flow rate of HFE-347mmy to a sum of flow rates of HFE-347mmy and PFP in the discharge gas is in a range of 10% to 90%.

4. The plasma etching method of claim 3, wherein a ratio of the sum of the flow rates of the HFE-347mmy and the PFP and a flow rate of the argon gas is in a range of 1:1 to 1:3.

5. The plasma etching method of claim 1, wherein a bias voltage applied to a substrate supporting the etching target thereon in the plasma chamber is in a range of −800 V to −400 V.

6. The plasma etching method of claim 1, wherein the etching target is a silicon nitride film or a silicon oxide film.
